(19) United States
(12) Patent Application Publication
(10) Pub. No.: US 2012/0236225 A1
(43) Pub. Date: Sep. 20, 2012

(54) DISPLAY DEVICE SUBSTRATE, MANUFACTURING METHOD OF DISPLAY DEVICE SUBSTRATE, DISPLAY DEVICE, AND MANUFACTURING METHOD OF DISPLAY DEVICE

(75) Inventor: Takashi Okamura, Osaka (JP)

(73) Assignee: SHARP KABUSHIKI KAISHA, Osaka (JP)

(21) Appl. No.: 13/513,163

(22) PCT Filed: Nov. 29, 2010
(86) PCT No.: PCT/JP2010/006949

§ 371 Date: May 31, 2012

(30) Foreign Application Priority Data
Dec. 1, 2009 (JP) 2009-273762

(51) Int. Cl. G02F 1/136; H01L 33/62; H01L 33/36; H01L 33/08

(52) U.S. Cl. 349/46; 257/59; 438/34; 438/30; 257/E33.056; 257/E33.062; 257/E33.053

(57) ABSTRACT

A liquid crystal display device (1) is provided with a gate insulating film (10) formed on an auxiliary capacitance line (9) which is formed on a glass substrate (7); a semiconductor layer (12) formed on the gate insulating film (10); a drain electrode (8) of a TFT (5) formed on the semiconductor (12); an interlayer insulation film (13) formed on the gate insulating film (10) so as to cover the semiconductor layer (12); and a pixel electrode (14) formed on the interlayer insulating film (13) and electrically connected to the drain electrode (8) via a contact hole (15) formed in the interlayer insulating film (13). Further, the drain electrode (8) is arranged at an approximate center (15a) of the contact hole (15).

### TECHNICAL FIELD

The present invention relates to a display device substrate in which a drain electrode and a pixel electrode are connected via a contact hole, a method of manufacturing the display device substrate, a display device, and a method of manufacturing the display device.

### BACKGROUND ART

In recent years, active matrix liquid crystal display devices that have advantageous features of thin-profile, light weight, low driving voltage and low power consumption have been widely used as display panels for various electronic devices such as mobile terminal equipment that includes cellular phones, mobile game consoles, and the like, and notebook personal computers.

Such active matrix liquid crystal display devices are provided with a thin-film transistor (hereinafter abbreviated as “TFT”) substrate that has TFTs as switching elements, a color filter substrate (hereinafter referred to as “CF substrate”) that has colored layers and that is bonded to the TFT substrate as an opposite substrate, and a liquid crystal layer disposed between these TFT substrate and CF substrate.

FIG. 20 is a plan view showing a structure of one pixel in the TFT substrate which constitutes the above-mentioned liquid crystal display device, and FIG. 21 is a cross-sectional view along the line C-C in FIG. 20.

A TFT substrate 50 has a glass substrate 60 as an insulating substrate. On this glass substrate 60, a plurality of data signal lines (hereinafter referred to as “source wiring lines”) 51 and a plurality of scan signal lines (hereinafter referred to as “gate wiring lines”) 52 are formed in a grid pattern to intersect with each other. Further, a plurality of auxiliary capacitance lines 53 are formed so as to extend in parallel with the plurality of gate wiring lines 52. At each of the intersections of these plurality of source wiring lines 51 and gate wiring lines 52, one corresponding pixel is provided.

Each pixel is provided with a TFT 56 as a switching element, in which the source electrode 54 is connected to the source wiring line 51 that passes through an intersection corresponding to the pixel, and the gate electrode 55 is connected to the gate wiring line 52 that passes through the same intersection.

An auxiliary capacitance electrode 61 is formed on the glass substrate 60, and over the auxiliary capacitance electrode 61, a semiconductor layer 63 is formed with an insulating film 62 interposed therebetween. On the semiconductor layer 63, a drain electrode 64 of the TFT 56 is formed, and on the drain electrode 64, an interlayer insulating film 65 is formed. On the interlayer insulating film 65, a pixel electrode 66 is formed.

The CF substrate that is disposed facing the TFT substrate 50 has a common electrode (or opposite electrode). The common electrode is commonly provided for the plurality of pixels arranged in a matrix, and is arranged so as to face the pixel electrodes 66 included in the respective pixels through the liquid crystal layer.

In the interlayer insulating film 65, a contact hole 67 is formed, and part of the contact hole 67 is in contact with the drain electrode 64. The pixel electrode 66 makes contact with ends 64a of the drain electrode 64 in the contact hole 67, thereby establishing an electrical connection between the pixel electrode 66 and the drain electrode 64.

A liquid crystal capacitance is formed by the pixel electrode 66 and the common electrode, and an auxiliary capacitance is formed by the pixel electrode 66 and the auxiliary capacitance line 53 provided along the gate wiring lines 52.

When the drain electrode 66 has a double layer structure of a titanium layer and an aluminum layer formed on the titanium layer, the aluminum layer that constitutes the drain electrode 64 may shrink and thereby form steps 68 (see FIG. 21), which causes a difficulty in establishing the connection between the drain electrode 64 and the pixel electrode 66. Therefore, as shown in FIG. 22, in order to increase the connection points of the drain electrode 64 and the pixel electrode 66, the end 64a of the drain electrode 64 is split into two at the contact hole 67 (see Patent Document 1, for example).

### RELATED ART DOCUMENT

### Patent Document

Patent Document 1: Japanese Patent Application Laid-Open Publication No. 2001-272698

### SUMMARY OF THE INVENTION

### Problems to be Solved by the Invention

Generally, the contact holes 67 for connecting the drain electrodes 64 and the pixel electrodes 66 are formed by patterning through the photolithography that includes forming a mask pattern, exposure and developing, and etching. In the photolithography process of forming the contact holes 67, a position alignment (hereinafter referred to as “alignment”) to the drain electrodes 64 which are already formed on the glass substrate 60 needs to be performed with a high degree of accuracy. Generally, the alignment accuracy of ± several μm or less is required. The alignment accuracy required for manufacturing active matrix substrates has been significantly high in recent years, and exposure devices to satisfy this requirement have been developed and put to practical use.

However, as described above, in the liquid crystal display device in the above-mentioned Patent Document 1, the ends 64a of the drain electrodes 64 are respectively split into two at the contact holes 67. Therefore, as shown in FIG. 23, if the contact holes 67 are made smaller than the designed size due to a decrease in the exposure light amount and the like, which causes the alignment to be off, in the photolithography steps of forming a mask, exposure, and developing, for example, the connection problem between the drain electrodes 64 and the pixel electrodes 66 occurs, resulting in display defects in the liquid crystal display device.

The present invention was made in view of the above-mentioned problem, and an object of the present invention is to provide a display device substrate in which the connection between the drain electrodes and the pixel electrodes can be ensured even if the contact holes for connecting the drain electrodes to the pixel electrodes are made small, a method of manufacturing the display device substrate, a display device, and a method of manufacturing the display device.

### Means for Solving the Problems

In order to achieve the above-mentioned object, a display device substrate of the present invention is provided with an insulating substrate, source wiring lines formed on the insulating substrate, a plurality of gate wiring lines formed on the insulating substrate so as to intersect with the source wiring lines, a plurality of auxiliary capacitance lines formed on the insulating substrate so as to extend in parallel with the gate wiring lines, a switching element provided at each of intersections of the source wiring lines and the gate wiring lines, an insulating film formed on the auxiliary capacitance lines, a semiconductor layer formed on the insulating film, a drain electrode of the switching element, which is formed on the semiconductor, an interlayer insulating film formed on the insulating film so as to cover the semiconductor layer, and a pixel electrode formed on the interlayer insulating film, the pixel electrode being connected to the drain electrode via a contact hole formed in the interlayer insulating film, wherein the drain electrode is located at an approximate center of the contact hole.

According to this configuration, the drain electrode is located at the approximate center of the contact hole, and therefore, even if the contact hole is made smaller than the designed size in forming the contact hole, the connection between the drain electrode and the pixel electrode can be ensured. Therefore, the connection problem between the drain electrode and the pixel electrode can be prevented, and as a result, the display defect can be prevented in the display devices having the display device substrate.

In the display device substrate of the present invention, an end of the drain electrode is formed so as to protrude outwardly from the contact hole in a plan view.

According to this configuration, the contact area of the drain electrode and the pixel electrode can be increased, and therefore, the connection between the drain electrode and the pixel electrode can be reliably ensured.

Alternatively, in the display device substrate of the present invention, the end of the drain electrode is formed in an inner region of the contact hole in a plan view.

According to this configuration, the size of the drain electrodes can be reduced, making it possible to reduce cost.

In the display device substrate of the present invention, the contact hole may have a substantially elliptical cross-section in a direction parallel to a plane of the display device substrate.

Alternatively, in the display device substrate of the present invention, the contact hole may have a substantially circular cross-section in a direction parallel to the plane of the display device substrate.

The display device substrate of the present invention has an excellent characteristic that the display defect can be prevented in the liquid crystal display device provided with the display device substrate. Therefore, the present invention is suitably used for a display device provided with a display device substrate, another display device substrate being disposed facing the display device substrate, and a display medium layer disposed between the display device substrate and the other display device substrate. The present invention is also suitably used for the display device in which the display medium layer is a liquid crystal layer.

A method of manufacturing the display device substrate of the present invention is a method of manufacturing a display device substrate provided with an insulating substrate, source wiring lines formed on the insulating substrate, a plurality of gate wiring lines formed on the insulating substrate so as to intersect with the source wiring lines, a plurality of auxiliary capacitance lines formed on the insulating substrate so as to extend in parallel with the gate wiring lines, and a switching element provided at each of intersections of the source wiring lines and the gate wiring lines, the method at least including: an insulating film forming step of forming an insulating film on the auxiliary capacitance lines, a semiconductor layer forming step of forming a semiconductor layer on the insulating film, a drain electrode forming step of forming the drain electrodes on the semiconductor layer, an interlayer insulating film forming step of forming an interlayer insulating film on the insulating film so as to cover the semiconductor layer, a contact hole forming step of forming contact holes in the interlayer insulating film and arranging the drain electrode at an approximate center of the contact hole, and a pixel electrode forming step of forming a pixel electrode on the interlayer insulating film and connecting the drain electrode to the pixel electrode via the contact hole.

According to this configuration, the contact holes are formed, and the drain electrodes are respectively arranged on the approximate centers of the contact holes, and therefore, even if the contact holes were formed smaller than the designed size in forming the contact holes, the connection of the drain electrodes and the pixel electrodes can be ensured. This makes it possible to prevent the connection problem between the drain electrodes and the pixel electrodes, and as a result, a liquid crystal display device having the display device substrate that can prevent the display defect can be provided.

In the method of manufacturing the display device substrate of the present invention, in the contact hole forming step, the contact hole is formed such that an end of the drain electrode protrudes outwardly from the contact hole in a plan view.

According to this configuration, the contact area of the drain electrode and the pixel electrode can be increased, and therefore, the connection between the drain electrode and the pixel electrode can be reliably ensured.

Alternatively, in the method of manufacturing the display device substrate of the present invention, in the contact hole forming step, the contact hole is formed such that an end of the drain electrode is located in an inner region of the contact hole in a plan view.

According to this configuration, the size of the drain electrodes can be reduced, making it possible to reduce cost.

In the method of manufacturing the display device substrate of the present invention, in the contact hole forming step, the contact hole may be formed so as to have a substantially elliptical cross-section in the direction parallel to the plane of the display device substrate.

Alternatively, in a method of manufacturing the display device substrate of the present invention, in the contact hole forming step, the contact hole may be formed so as to have a substantially circular cross-section in the direction parallel to the plane of the display device substrate.

The method of manufacturing the display device substrate of the present invention has an excellent characteristic of providing a liquid crystal display device having a display device substrate that can prevent the display defect. Therefore, the present invention is suitably used for a method of manufacturing the display device that at least includes preparing a display device substrate, disposing another display device substrate so as to face the display device substrate, and disposing a display medium layer between the display device substrate and the other display device substrate. Also, the present invention is suitably used for a method of manufacturing a display device in which a display medium layer is a liquid crystal layer.

### Effects of the Invention

According to the present invention, the connection problem between the drain electrodes and the pixel electrodes can be prevented, and thus, the display defect can be prevented in the liquid crystal display device provided with the display device substrate.

### BRIEF DESCRIPTION OF THE DRAWINGS

FIG. 1 is a plan view showing an overall configuration of a liquid crystal display device according to an embodiment of the present invention.

FIG. 2 is a cross-sectional view of a liquid crystal display device according to an embodiment of the present invention.

FIG. 3 is a plan view showing a pixel in a liquid crystal display device according to an embodiment of the present invention.

FIG. 4 is a cross-sectional view along the line A-A in FIG. 3.

FIG. 5 is a cross-sectional view showing an overall configuration of a display unit of the liquid crystal display device according to an embodiment of the present invention.

FIG. 6 is a plan view of a contact region in which a drain electrode and a pixel electrode are connected in a liquid crystal display device according to an embodiment of the present invention.

FIG. 7 is a figure for explaining a method of manufacturing a liquid crystal display device according to an embodiment of the present invention.

FIG. 8 is a figure for explaining a method of manufacturing the liquid crystal display device according to the embodiment of the present invention.

FIG. 9 is a figure for explaining a method of manufacturing the liquid crystal display device according to the embodiment of the present invention.

FIG. 10 is a figure for explaining a method of manufacturing the liquid crystal display device according to the embodiment of the present invention.

FIG. 11 is a figure for explaining a method of manufacturing the liquid crystal display device according to the embodiment of the present invention.

FIG. 12 is a figure for explaining a method of manufacturing the liquid crystal display device according to the embodiment of the present invention.

FIG. 13 is a figure for explaining a method of manufacturing the liquid crystal display device according to the embodiment of the present invention.

FIG. 14 is a figure for explaining a method of manufacturing the liquid crystal display device according to the embodiment of the present invention.

FIG. 15 is a cross-sectional view along the line B-B in FIG. 3 when part of an aluminum layer is etched.

FIG. 16 is a cross-sectional view along the line B-B in FIG. 3 when a pixel electrode is formed, and the drain electrode and the pixel electrode are connected.

FIG. 17 is a figure for explaining a method of manufacturing the liquid crystal display device according to the embodiment of the present invention.

FIG. 18 is a figure for explaining a modification example of a contact hole in the liquid crystal display device according to the embodiment of the present invention.

FIG. 19 is a figure for explaining a modification example of an arrangement of the drain electrode in the liquid crystal display device according to the embodiment of the present invention.

FIG. 20 is a plan view showing a pixel in a conventional liquid crystal display device.

FIG. 21 is a cross-sectional view along the line C-C in FIG. 20.

FIG. 22 is a plan view showing a conventional liquid crystal display device in which a drain electrode and a pixel electrode are connected.

FIG. 23 is a plan view showing the conventional liquid crystal display device in which the contact hole is formed small.

### DETAILED DESCRIPTION OF EMBODIMENTS

Below, an embodiment of the present invention will be described in detail referring to the figures. The present invention is not limited to the embodiment below.

### Embodiment 1

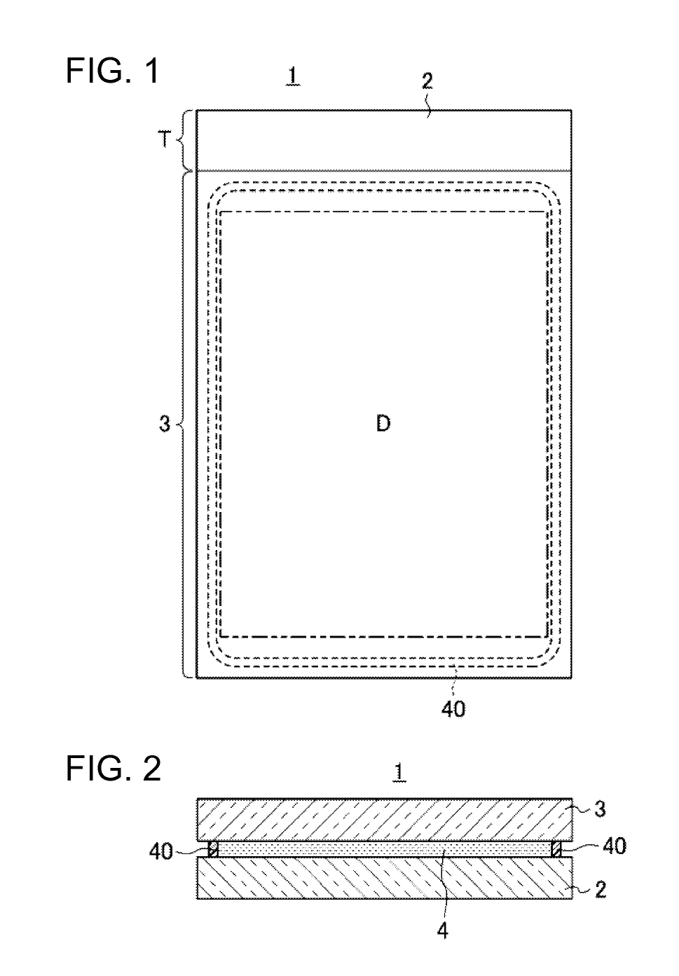

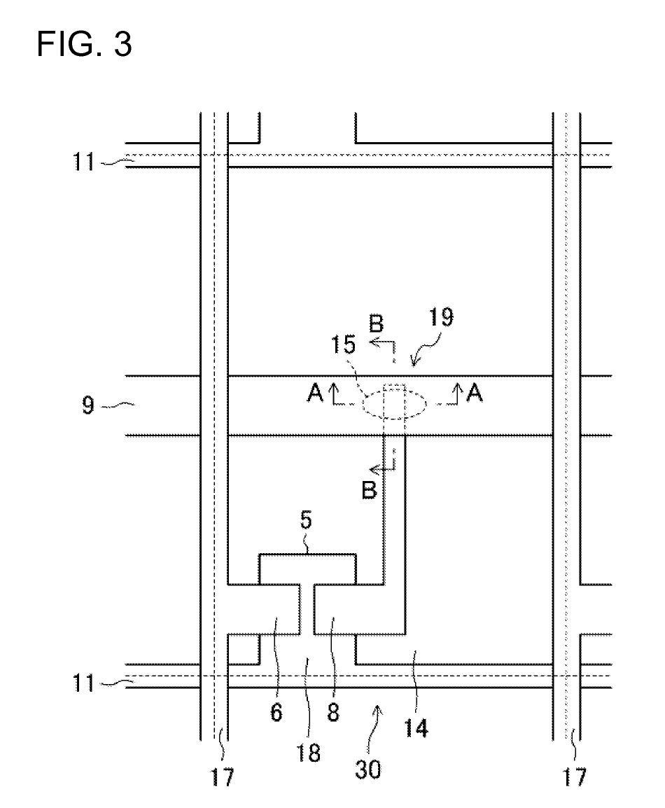

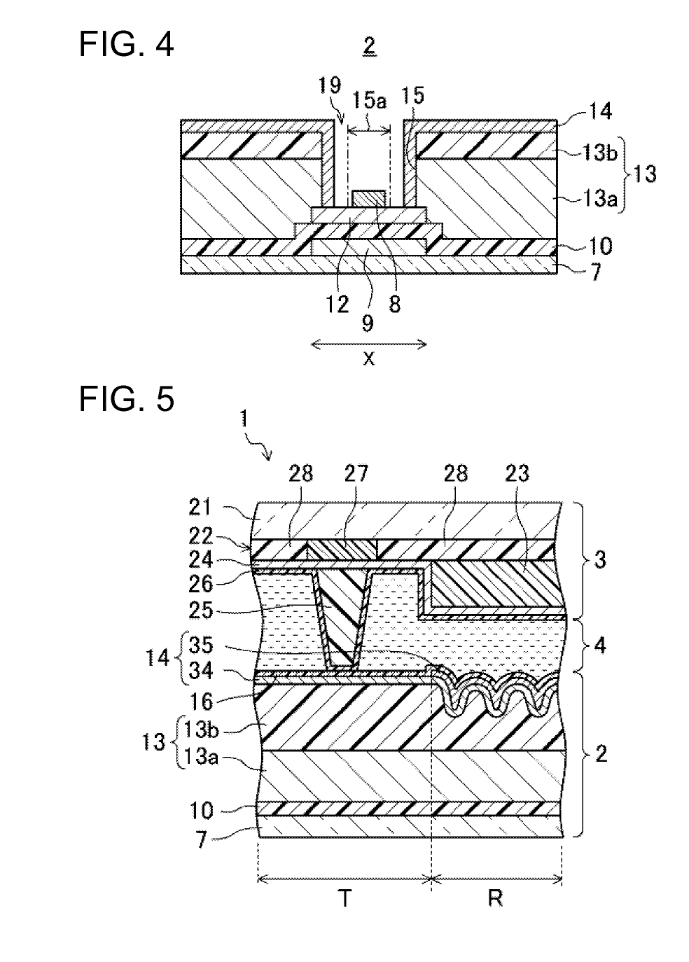

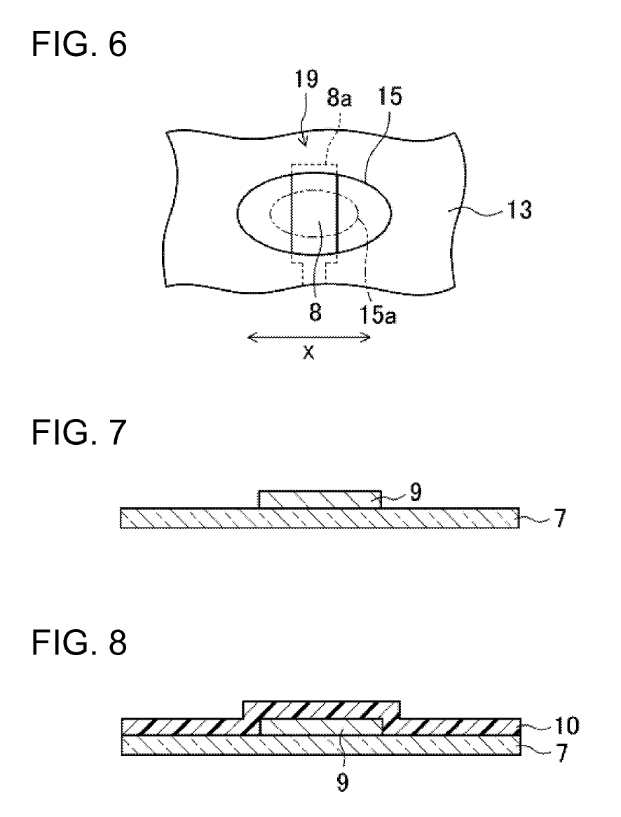

FIG. 1 is a plan view showing an overall configuration of a liquid crystal display device according to an embodiment of the present invention; FIG. 2 is a cross-sectional view of the liquid crystal display device according to the embodiment of the present invention; FIG. 3 is a plan view showing a pixel in the liquid crystal display device according to the embodiment of the present invention; FIG. 4 is a cross-sectional view along the line A-A in FIG. 3; FIG. 5 is a cross-sectional view showing the overall configuration of the display unit of the liquid crystal display device according the embodiment of the present invention; FIG. 6 is a plan view of a contact region in which a drain electrode and a pixel electrode are connected in the liquid crystal display device according to the embodiment of the present invention.

As shown in FIGS. 1 and 2, the liquid crystal display device 1 is provided with a TFT substrate 2 that is a first substrate, a CF substrate 3 that is a second substrate disposed facing the TFT substrate 2, and a liquid crystal layer 4 that is a display medium layer held between the TFT substrate 2 and the CF substrate 3. The liquid crystal display device 1 is further provided with a sealing material 40 held between the TFT substrate 2 and the CF substrate 3 in a frame shape for bonding the TFT substrate 2 and the CF substrate 3 to each other and for sealing the liquid crystal layer 4.

The liquid crystal layer 4 is made of nematic liquid crystal materials having the electrooptic characteristics and the like, for example.

The sealing material 40 is formed so as to enclose the liquid crystal layer 4, and the TFT substrate 2 and the CF substrate 3 are bonded to each other through this sealing material 40. The liquid crystal display device 1 is provided with a plurality of photospacers 25 (see FIG. 5) to control the thickness (that is, a cell gap) of the liquid crystal layer 4.

Also, as shown in FIG. 1, the liquid crystal display device 1 is formed in a rectangular shape. The TFT substrate 2 is extended beyond the CF substrate 3 in the long side direction of the liquid crystal display device 1, and on the extended area, a plurality of display wiring lines such as gate wiring lines and source wiring lines, which will be described later, are led out, thereby forming a terminal region T.

In the liquid crystal display device 1, a display region D for displaying an image is defined in a region where the TFT substrate 2 and the CF substrate 3 overlap. The display region D is made of a plurality of pixels, which respectively are the smallest units of an image, arranged in a matrix.

As shown in FIG. 1, the sealing material 40 is formed in a rectangular frame shape that surrounds the entire periphery of the display region D.

As shown in FIG. 3, in a pixel 30 provided in the liquid crystal display device 1, a source wiring 17 and a gate wiring 11 are arranged so as to intersect with each another. In other words, at each of the intersections of the plurality of source wiring lines 17 and the gate wiring lines 11, one corresponding pixel 30 is provided.

Although FIG. 3 shows only one pixel, both source wiring lines 17 and the gate wiring lines 11 are provided plurally, and the plurality of pixels 30 are arranged in a matrix so as to correspond to the respective intersections of the plurality of source wiring lines 17 and the plurality of gate wiring lines 11. In other words, the pixels 30 are respectively formed in respective regions that are enclosed by the gate wiring lines 11 and the source wiring lines 17.

A gate electrode 18 is connected to the gate wiring line 11 adjacent to an intersection of the two signal lines, and a source electrode 6 is connected to the source wiring line 17 adjacent to the same intersection. Further, a thin-film transistor (TFT) 5 having the drain electrode 8 connected to the pixel electrode 14 is provided as a switching element. The TFT 5 is turned on when the gate wiring line 11 is selected, and is turned off when the gate wiring line 11 is not selected. As shown in FIG. 3, the TFT 5 is provided at each of the intersections of the gate wiring lines 11 and the source wiring lines 17.

The drain electrode 8 has a double-layered film of a titanium layer and an aluminum layer formed on the titanium layer, for example. However, the structure of the drain electrode 8 is not limited to such, and it may be formed of only a titanium layer or only an aluminum layer, for example.

The pixel electrode 14 is made of ITO (Indium Tin Oxide), for example.

As shown in FIG. 4, the TFT substrate 2 is provided with a glass substrate 7 as an insulating substrate, and on the glass substrate 7, the above-mentioned gate wiring lines 11 and the source wiring lines 17 are formed in a grid pattern to intersect with each other. As shown in FIG. 3, auxiliary capacitance lines 9 are formed so as to extend in parallel with the plurality of gate wiring lines 11. The auxiliary capacitance line 9 is formed on the glass substrate 7 as shown in FIG. 4; and a semiconductor layer 12 is formed above the auxiliary capacitance line 9 having a gate insulating film 10 therebetween.

This semiconductor layer 12 is made of a silicon layer, which includes an intrinsic amorphous silicon layer in a lower layer and a phosphorus-doped n⁺ amorphous silicon layer in an upper layer, for example.

On the semiconductor layer 12, the drain electrode 8 of the TFT 5 and an interlayer insulating film 13 are formed, and on the interlayer insulating film 13, the pixel electrode 14 is formed. As shown in FIG. 5, the TFT substrate 2 is provided with an alignment film 16 disposed so as to cover the respective pixel electrodes 14.

As shown in FIG. 4, the interlayer insulating film 13 includes a protective film 13a, which is disposed so as to cover the auxiliary capacitance line 9 and the semiconductor layer 12, and an organic film 13b formed on the protective film 13a.

There is no special limitation on the material of the protective film 13a, and oxide silicon (SiO₂), silicon nitride (SiNₓ (x is a positive number)), and the like can be used, for example. For the material of the organic film 13b, a positive-type photosensitive acrylic resin, a negative-type photosensitive resin, and the like, which has an insulating property, can be used, for example.

The interlayer insulating film 13 may have a multilayer structure in which two or more layers of an organic film and an inorganic film are laminated.

As shown in FIG. 5, the pixel electrode 14 is constituted of a transparent electrode 34 provided on the interlayer insulating film 13 and a reflective electrode 35 formed on the surface of the transparent electrode 34 so as to be laminated on the transparent electrode 34.

As shown in FIG. 4, a contact hole 15 is formed in the interlayer insulating film 13, and part of the contact hole 15 is in contact with the drain electrode 8. When the pixel electrode 14 is in contact with the drain electrode 8 in the contact hole 15, the pixel electrode 14 and the drain electrode 8 are electrically connected. In other words, it is configured such that the drain electrode 8 is connected to the pixel electrode 14 through the contact hole 15 formed in the interlayer insulating film in a contact region 19 where the drain electrode 8 and the pixel electrode 14 are connected.

As shown in FIG. 6, the contact hole 15 has a substantially elliptical cross-section in a direction (the direction indicated in FIG. 4 and FIG. 6 by an arrow X) parallel with the plane of the TFT substrate 2 (and the plane of the CF substrate 3).

As shown in FIG. 5, in the display region D of the TFT substrate 2 and of the liquid crystal display device 1 provided with the TFT substrate 2, a reflective region R is defined by the reflective electrode 35, and a transmissive region T is defined by the transparent electrode 34, which is exposed from the reflective electrode 35. As shown in FIG. 5, the surface of the organic film 13b under the pixel electrode 14 has recesses and protrusions, and the surface of the reflective electrode 35 disposed over the organic film 13b through the transparent electrode 34 also has recesses and protrusions.

The above-mentioned reflective region R does not necessarily need to be defined, and a configuration where only the transmissive region T is defined may be employed.

As shown in FIG. 5, the CF substrate 3 has a glass substrate 21 as an insulating substrate, a color filter layer 22 arranged on the glass substrate 21, and a transparent layer 23 disposed in the reflective region R of the color filter layer 22 so as to compensate for the optical path difference between the reflective region R and the transmissive region T. In the CF substrate 3, a common electrode 24 is disposed so as to cover the color filter layer 22 in the transmissive region T and the transparent layer 23 (namely, the reflective region R), a photospacer 25 having a columnar shape is formed on the common electrode 24, and an alignment film 26 is disposed so as to cover the common electrode 24 and the photospacer 25. The color filter layer 22 includes colored layers 28 having red layers R, green layers G, and blue layers B, arranged so as to correspond to the respective pixels, and a black matrix 27, which is a light shielding film. As shown in FIG. 5, the common electrode 24 is disposed facing the pixel electrodes 14 through the liquid crystal layer 4.

A liquid crystal capacitance is formed by the pixel electrode 14 and the common electrode 24, and an auxiliary capacitance is formed by the pixel electrode 14 and the auxiliary capacitance line 9 provided along the gate wiring line 11.

The transflective liquid crystal display device 1 having the above-mentioned structure is configured to reflect light that enters from the side of the CF substrate 3 at the reflective electrode 35 in the reflective region R, and to transmit light from a backlight (not shown) that enters from the side of the TFT substrate 2 in the transmissive region T.

In the liquid crystal display device 1, display signals (data signals) corresponding to the display states of the pixels 30 are supplied from a not-shown data signal line driving unit (source driver) to the source wiring lines 17, and a scan signal (gate signal) to turn on and off the TFTs 5 are supplied from a not-shown scan signal line driving unit (gate driver) to the gate wiring lines 11.

The liquid crystal display device 1 is configured as follows: when the gate signal is provided from the gate wiring lines 11, and thereby turns on the TFTs 5 in the pixels 30 provided for the respective pixel electrodes 14, the data signals are supplied from the source wiring lines 17, and prescribed electric charges are written in the pixel electrodes 14 via the source electrodes 6 and the drain electrodes 8. This creates a potential difference between the pixel electrodes 14 and the common electrodes 24, and as a result, a prescribed voltage is applied to the liquid crystal layer 4. The orientation state of the liquid crystal molecules is changed depending on a size of the voltage applied thereto, and the liquid crystal display 1 is configured to adjust the transmittance of the incoming light from the backlight by utilizing this property, thereby displaying images.

In this embodiment, as shown in FIGS. 4 and 6, the drain electrode 8 in the contact region 19 is disposed at the approximate center 15a of the contact hole 15.

With this configuration, in forming the contact holes 15 by patterning through the photolithography that includes forming a mask pattern, exposure and developing, and etching, even if the contact holes 15 are made smaller than the designed size due to a misalignment, the connection between the drain electrodes 8 and the pixel electrodes 14 can be ensured. Therefore, the connection problem of the drain electrodes 8 and the pixel electrodes 14 can be prevented.

As shown in FIG. 6, an end 8a of the drain electrode 8 is formed so as to protrude outwardly from the contact hole 15 in a plan view (in the direction parallel with the plane of the TFT substrate 2 (namely, the direction indicated in FIG. 6 by an arrow X)).

In such a configuration, the contact area of the drain electrode 8 and the pixel electrode 14 can be increased.

Next, a method of manufacturing a liquid crystal display device of the present embodiment will be described using an example. FIGS. 7 to 13 are cross-sectional view along the line A-A in FIG. 3 for explaining a method of manufacturing a liquid crystal display device according to an embodiment of the present invention. The method of manufacturing the liquid crystal display device in this embodiment includes a TFT substrate fabricating process, a CF substrate fabricating process, and a substrate bonding process.

TFT Substrate Fabricating Process

First, as shown in FIG. 7, a multilayer film is formed by sputtering on an entire glass substrate 7 by depositing a titanium film, an aluminum film, a titanium film, and the like in this order, for example. Thereafter, patterning is performed by the photolithography so as to form gate wirings 11, gate electrodes 18, and auxiliary capacitance lines 9 with the approximate thickness of 4000 Å.

Next, as shown in FIG. 8, on the entire substrate in which the gate wirings 11, the gate electrodes 18, and the auxiliary capacitance lines 9 have been formed, a silicon nitride film or the like, for example, is deposited by the plasma CVD (Chemical Vapor Deposition) method, thereby forming the gate insulating film 10 with the approximate thickness of 400 nm on the auxiliary capacitance lines 9.

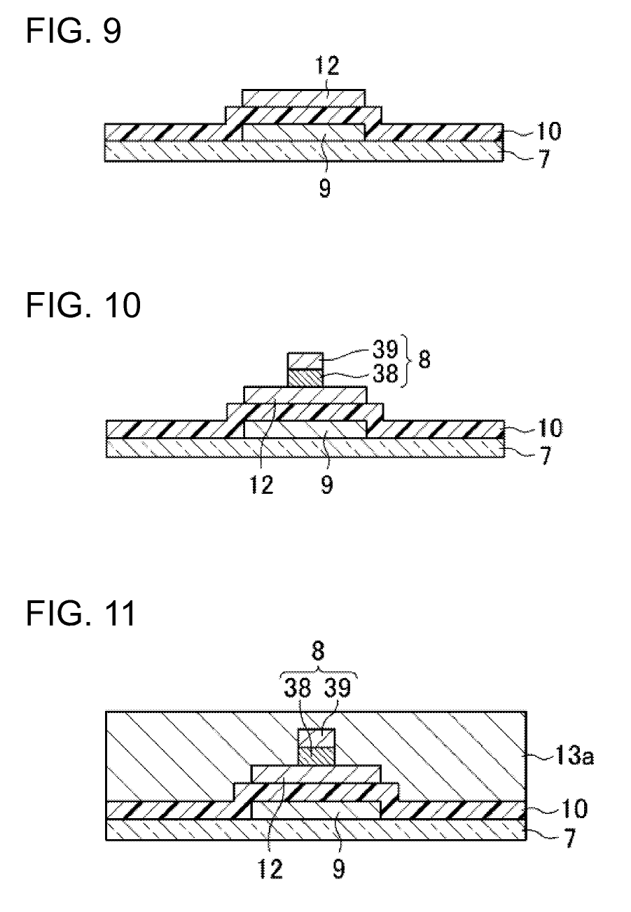

Further, on the entire substrate in which the gate insulating film 10 has been formed, an intrinsic amorphous silicon film and a phosphorus-doped n⁺ amorphous silicon film, for example, are continuously formed by the plasma CVD method. Thereafter, by patterning these films into an island shape on the gate electrode 18 by the photolithography, a semiconductor forming layer, in which the intrinsic amorphous silicon layer and the n⁺ amorphous silicon layer are laminated, is formed. Next, the n⁺ amorphous silicon layer of the semiconductor forming layer is etched so as to form a channel region, and a semiconductor layer 12 is thereby formed on the gate insulating film 10 with the approximate thickness of 100 nm as shown in FIG. 9.

Next, as shown in FIG. 10, an aluminum layer 38 and a titanium layer 39, for example, are deposited in this order by sputtering on the entire substrate in which the semiconductor layers 12 have been formed. Thereafter, by patterning these layers by the photolithography, the drain electrode 8 is formed on the semiconductor layer 12 with the approximate thickness of 400 nm. At this time, the source wiring lines 17 and the source electrodes 6 are also formed, and as a result, the TFTs 5 having the semiconductor layers 12 are formed.

Next, as shown in FIG. 11, the protective film 13a with the approximate thickness of 200 nm is formed by depositing a silicon nitride film or the like, for example, by the plasma CVD method on the entire substrate in which the TFTs 5 have been formed.

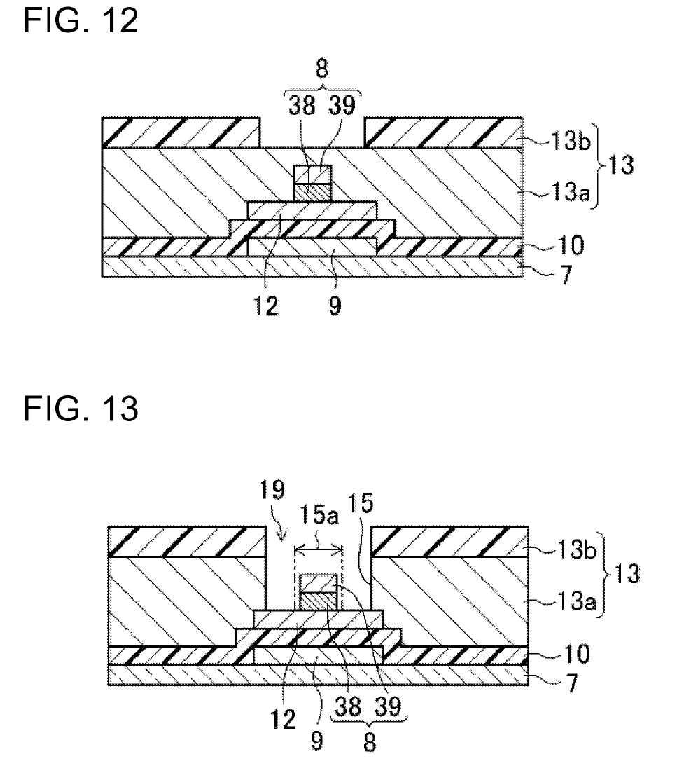

Subsequently, as shown in FIG. 12, a positive-type photosensitive acrylic resin is deposited on the entire substrate in which the protective film 13a has been formed, and by patterning the resin by the photolithography, the organic film 13b with the approximate thickness of 3 μm is formed on the surface of the protective film 13a, thereby forming the interlayer insulating film 13 made of the protective film 13a and the organic film 13b on the gate insulating film 10.

Next, as shown in FIG. 13, by performing patterning through the photolithography that includes forming a mask pattern, exposure and developing, and etching, the interlayer insulating film 13 (namely, the protective layer 13a and the organic film 13b) is etched, and the contact hole 15 is thereby formed.

Here, as described above, the contact hole 15 is formed such that the drain electrode 8 in the contact regions 19 is located at the approximate center 15a of the contact hole 15. Also, the contact hole 15 is formed such that the end 8a of the drain electrode 8 protrudes outwardly from the contact hole 15 in a plan view.

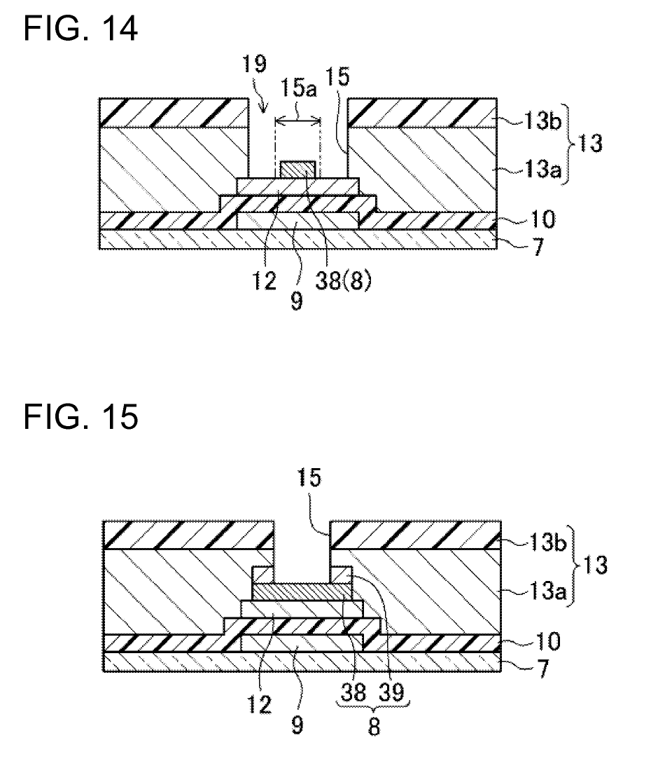

Next, as shown in FIG. 14, the aluminum layer 38 that constitutes the drain electrode 8 is partially removed by etching. FIG. 15 shows a cross-sectional view along the line B-B in FIG. 3 when the part of the aluminum layer 38 is etched.

Next, the transparent electrode 34 is formed on the glass substrate 7 by depositing a transparent conductive film made of an ITO film by sputtering on the interlayer insulating film 13 so as to cover the entire substrate, and by thereafter patterning the film by the photolithography.

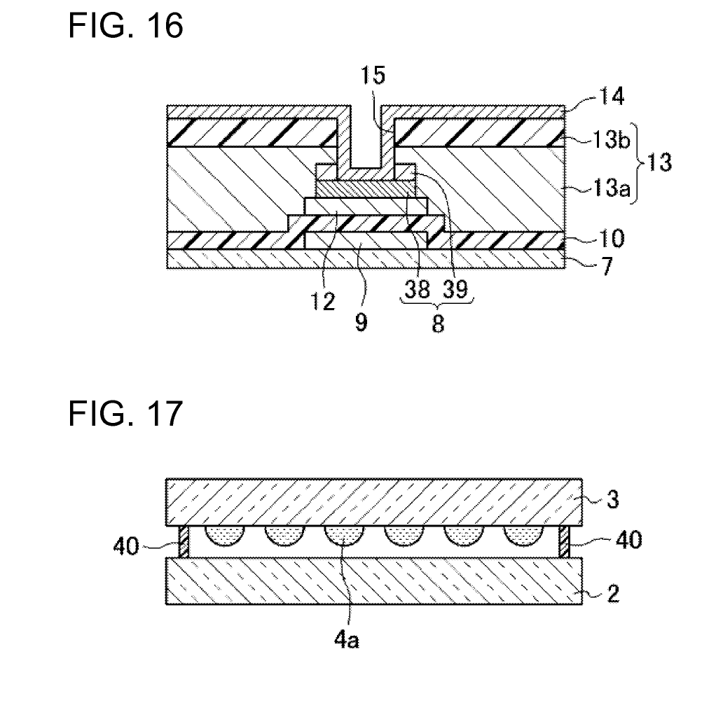

Next, on the entire substrate in which the transparent electrode 34 has been formed, a molybdenum film and an aluminum film are deposited in this order by sputtering, and thereafter, these films are patterned by the photolithography so as to form the reflective electrode 35 on the surface of the transparent electrode 34 in the reflective region R. Next, as shown in FIG. 4, the pixel electrode 14 having the transparent electrode 34 and the reflective electrode 35 is formed on the interlayer insulating film 13 with the approximate thickness of 10 nm, and the drain electrode 8 located at the approximate center 15a of the contact hole 15 and the pixel electrode 14 are connected via the contact hole 15. FIG. 16 shows a cross-sectional view along the line B-B in FIG. 3 when the pixel electrode 14 is formed and the drain electrode 8 and the pixel electrode 14 are connected.

Next, on the entire substrate in which the pixel electrodes 14 are formed, the alignment film 16 is formed with the approximate thickness of 1000 Å by applying a polyimide resin by a printing method, and by thereafter performing a rubbing treatment.

The TFT substrate 2 can be fabricated in the manner described above.

CF Substrate Fabricating Process

First, the entire surface of the glass substrate 21 is coated with a positive-type photosensitive resin having black pigment such as carbon particles dispersed therein using the spin coat method, for example, and thereafter, the applied photosensitive resin is exposed through a photomask, and by developing and heat-treating the exposed resin, the black matrix 27 with the approximate thickness of 2.0 μm is formed.

Next, an acrylic photosensitive resin, which is colored in red, green, or blue, for example, is applied on the substrate where the black matrix 27 has been formed, and the applied photosensitive resin is exposed through a photo mask and subsequently developed so as to be patterned. As a result, colored layers of a selected color (for example, a red layer R) 28 with the approximate thickness of 2.0 μm are formed. The same steps are repeated for the other two colors, thereby forming the colored layers of the other two colors (green layers G and blue layers B, for example) 28 with the approximate thickness of 2.0 μm. This way, the color filter layer 22 having the red layers R, the green layers G, and the blue layers B is formed.

Next, an acrylic photosensitive resin is applied by the spin coat method on the substrate in which the color filter layer 22 is formed, and by exposing the applied photosensitive resin using a photomask, and developing the resin after the exposure, the transparent layer 23 with the approximate thickness of 2 μm is formed.

Next, an ITO film, for example, is deposited by sputtering on the entire substrate in which the transparent layer 23 has been formed, and thereafter, by patterning the film by the photolithography, the common electrode 24 with the approximate thickness of 1500 Å is formed.

Next, an acrylic photosensitive resin is applied by the spin coat method on the entire substrate in which the common electrodes 24 are formed, and by exposing the applied photosensitive resin through a photomask, and developing the resin after the exposure, the photospacers 25 are formed with the approximate thickness of 4 μm.

Lastly, the alignment film 26 with the approximate thickness of 1000 Å is formed by applying a polyimide resin on the entire substrate in which the photospacers 25 have been formed by the printing method, and by performing a rubbing treatment for the polyimide resin.

The CF substrate 3 can be fabricated in the manner described above.

Substrate Bonding Process

First, a sealing material 40 is formed in a frame shape using a dispenser, for example, on the CF substrate 3 which was prepared through the above-mentioned CF substrate fabricating process. The sealing material 40 is made of a UV-curable and thermosetting resin or the like.

Next, liquid crystal materials are dropped on a region inside of the sealing material 40 on the CF substrate 3 having the sealing material 40 formed thereon.

Further, as shown in FIG. 17, the CF substrate 3 having the liquid crystal materials 4a dropped thereon and the TFT substrate 2 that was prepared through the above-mentioned TFT substrate fabricating process are disposed so as to face each other, and are bonded under the reduced pressure. Thereafter, the bonded laminated body is exposed to the atmospheric pressure such that a pressure is applied to the front surface and to the rear surface of the laminated body, thereby forming the liquid crystal layer 4 as a display medium layer between the TFT substrate 2 and the CF substrate 3 as shown in FIG. 2.

Next, the sealing material 40 is cured by radiating UV light to the sealing material 40 held by the laminated body, and by heating the laminated body thereafter.

The liquid crystal display device 1 shown in FIG. 1 can be manufactured in the manner described above.

According to the present embodiment described above, the following effects can be obtained.

(1) This embodiment is configured such that the drain electrodes 8 are located at the approximate centers 15a of the contact holes 15 in the contact regions 19, respectively. Therefore, even if the contact holes 15 are formed smaller than the designed size in forming the contact holes 15 by patterning through the photolithography that includes forming a mask pattern, exposure and developing, and etching, the connection between the drain electrodes 8 and the pixel electrodes 14 can be ensured. Therefore, the connection problem between the drain electrodes 8 and the pixel electrodes 14 can be prevented, and as a result, the display defect in the liquid crystal display device 1 can be prevented.

(2) This embodiment is configured such that the ends 8a of the drain electrodes 8 respectively protrude outwardly from the contact holes 15 in a plan view. Therefore, even if the drain electrodes 8 are located at the approximate centers 15a of the contact holes 15, the contact areas of the drain electrodes 8 and the pixel electrodes 14 can be maximized, and thus, the connection between the drain electrodes 8 and the pixel electrodes 14 can be reliably ensured.

The above-mentioned embodiment may be modified as follows.

In the above-mentioned embodiment, the contact holes 15 were formed in a substantially elliptical shape; but the contact holes 15 may also be formed to have a substantially circular cross-section in the direction X parallel with the plane of the TFT substrate 2 (and the plane of the CF substrate 3). In this case, in a manner similar to the above-mentioned Embodiment 1, by arranging the drain electrodes 8 so as to be located at the approximate centers 15a of the contact holes 15 in the contact region 19, respectively, the same effect as the above-mentioned (1) can be obtained.

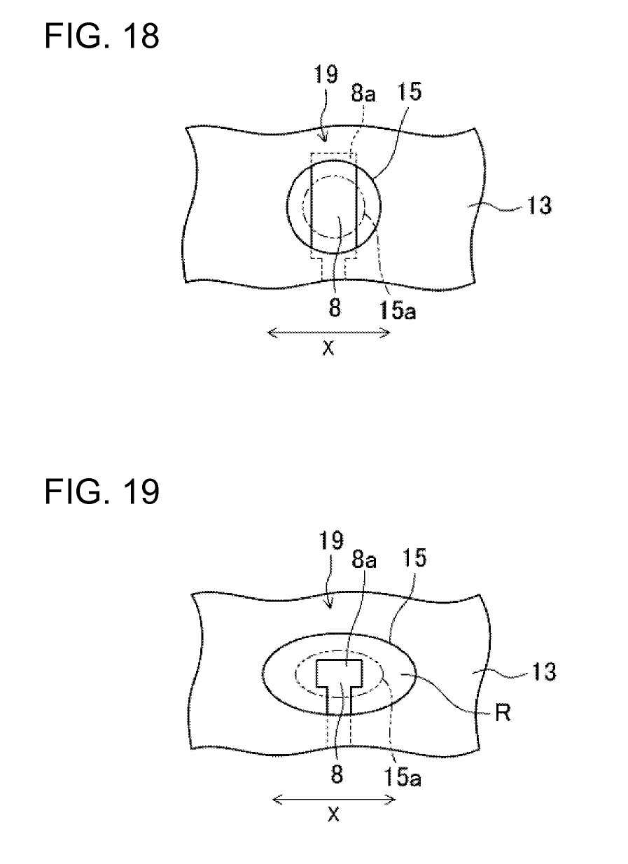

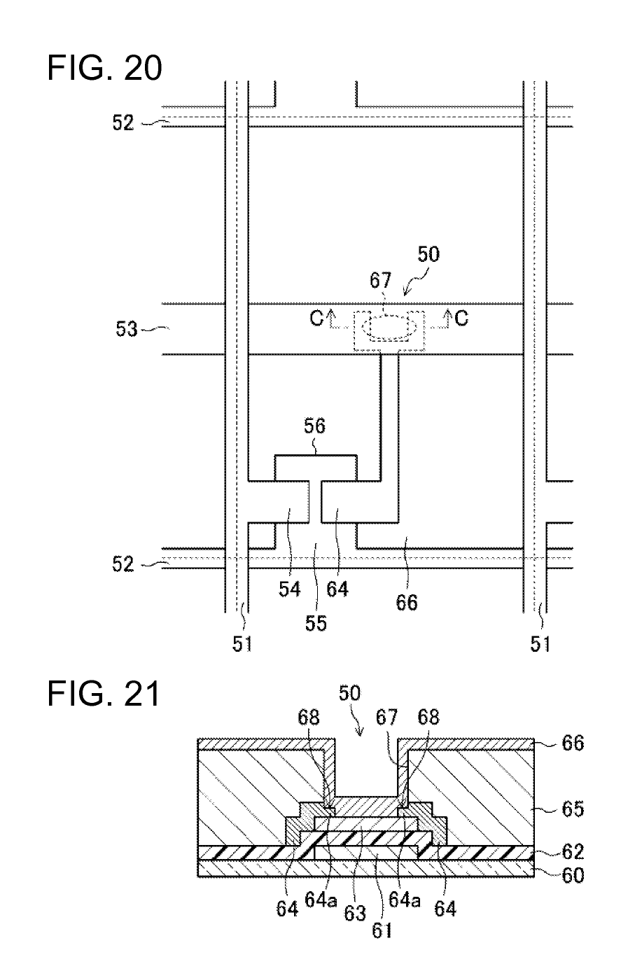

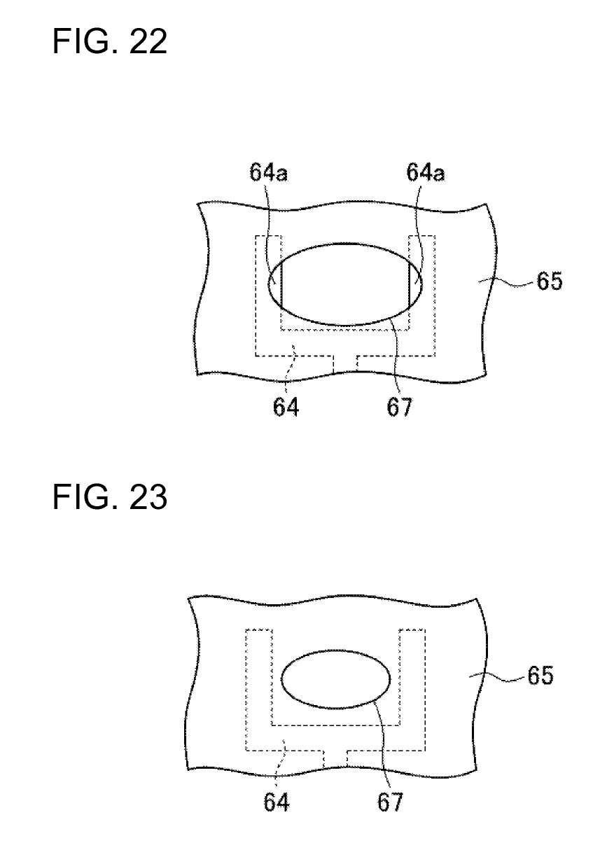

Even when the contact holes 15 are formed in a substantially circular shape, by employing a configuration in which the ends 8a of the drain electrodes 8 protrude outwardly from the contact holes 15, respectively, in a plan view as shown in FIG. 18, the same effect as the above-mentioned (2) can be obtained.

In the above-mentioned embodiment, the ends 8a of the drain electrodes 8 were formed so as to protrude outwardly from the contact holes 15, respectively, in a plan view; but as shown in FIG. 19, the ends 8a of the drain electrodes 8 may be arranged in regions R in the contact holes 15, respectively, in a plan view. In other words, in forming the contact holes 15, the contact holes 15 may be configured such that the ends 8a of the drain electrodes 8 are located in the inner regions of the contact holes 15, respectively, in a plan view. In this case, in a manner similar to the above-mentioned Embodiment 1, the drain electrodes 8 are located at the approximate centers 15a of the contact holes 15 in the contact regions 19, and therefore, the same effect as the above-mentioned (1) can be obtained. Also, in such a configuration, the size of the drain electrode 8 can be reduced; thus, it becomes possible to reduce cost.

In this case, the contact hole 15 may also be formed to have a substantially circular cross-section in the direction X parallel with the plane of the TFT substrate 2.

In the above-mentioned embodiment, the transflective liquid crystal display device was described as an example, but the present invention can also be applied to a reflective liquid crystal display device.

The mode of the liquid crystal display device 1 of the above-mentioned embodiment may be any modes such as the TN (Twisted Nematic) mode, the VA (Vertical Alignment) mode, the MVA (Multi-domain Vertical Alignment) mode, the ASV (Advanced Super View) mode, and the IPS (In-Plane-Switching) mode.

### INDUSTRIAL APPLICABILITY

The present invention can be used for a liquid crystal display device in which drain electrodes and pixel electrodes are connected via contact holes, and for a manufacturing method thereof, for example.

### DESCRIPTION OF REFERENCE CHARACTERS

1 liquid crystal display device

2 TFT substrate (display device substrate)

3 CF substrate (another display device substrate)

4 liquid crystal layer (display medium layer)

5 TFT (switching element)

7 glass substrate (insulating substrate)

8 drain electrode

8a end of drain electrode

9 auxiliary capacitance line

10 gate insulating film (insulating film)

11 gate wiring

12 semiconductor layer

13 interlayer insulating film

14 source wiring

15 contact hole

15a approximate center of contact hole

R contact hole region

X direction parallel with plane of TFT substrate

1. A display device substrate, comprising:
an insulating substrate;
source wiring lines formed on said insulating substrate;
a plurality of gate wiring lines formed on said insulating substrate so as to intersect with said source wiring lines;
a plurality of auxiliary capacitance lines formed on said insulating substrate so as to extend in parallel with said gate wiring lines;
a switching element provided at each of intersections of said source wiring lines and said gate wiring lines;
an insulating film formed on said auxiliary capacitance lines;
a semiconductor layer formed on said insulating film;
a drain electrode of said switching element, formed on said semiconductor layer;
an interlayer insulating film formed on said insulating film so as to cover said semiconductor layer; and
a pixel electrode formed on said interlayer insulating film, the pixel electrode being electrically connected to said drain electrode via a contact hole formed in said interlayer insulating film;
wherein said drain electrode is located at an approximate center of said contact hole.

2. The display device substrate according to claim 1, wherein an end of said drain electrode is formed so as to protrude outwardly from said contact hole in a plan view.

3. The display device substrate according to claim 1, wherein the end of said drain electrode is formed in an inner region of said contact hole in a plan view.

4. The display device substrate according to claim 1, wherein said contact hole has a substantially elliptical cross-section parallel to a plane of said display device substrate.

5. The display device substrate according to claim 1, wherein said contact hole has a substantially circular cross-section parallel to a plane of said display device substrate.

6. A display device, comprising:
the display device substrate according to claim 1;
another display device substrate disposed so as to face said display device substrate; and
a display medium layer disposed between said display device substrate and said another display device substrate.

7. The display device according to claim 6, wherein said display medium layer is a liquid crystal layer.

8. A method of manufacturing a display device substrate that includes an insulating substrate, source wiring lines formed on said insulating substrate, a plurality of gate wiring lines formed on said insulating substrate so as to intersect with said source wiring lines, a plurality of auxiliary capacitance lines formed on said insulating substrate so as to extend in parallel with said gate wiring lines, and a switching element provided at each of intersections of said source wiring lines and said gate wiring lines, the method comprising:
an insulating film forming step of forming an insulating film on said auxiliary capacitance lines;
a semiconductor layer forming step of forming a semiconductor layer on said insulating film;
a drain electrode forming step of forming a drain electrode on said semiconductor layer;
an interlayer insulating film forming step of forming an interlayer insulating film on said insulating film so as to cover said semiconductor layer;
a contact hole forming step of forming a contact hole in said interlayer insulating film such that said drain electrode is disposed at an approximate center of said contact hole; and
a pixel electrode forming step of forming a pixel electrode on said interlayer insulating film to connect said drain electrode to said pixel electrode via said contact hole.

9. The method of manufacturing the display device substrate according to claim 8, wherein, in the step of forming said contact hole, said contact hole is formed such that an end of said drain electrode protrudes outwardly from said contact holes in a plan view.

10. The method of manufacturing the display device substrate according to claim 8, wherein, in the step of forming said contact hole, said contact hole is formed such that an end of said drain electrode is located in an inner region of said contact hole in a plane view.

11. The method of manufacturing the display device substrate according to claim 8, wherein, in the step of forming said contact hole, said contact hole is formed to have a substantially elliptical cross-section parallel to a plane of said display device substrate.

12. The method of manufacturing the display device substrate according to claim 8, wherein, in the step of forming said contact hole, said contact hole is formed to have a substantially circular cross-section parallel to a plane of said display device substrate.

13. A method of manufacturing a display device, comprising:
preparing a display device substrate manufactured by the manufacturing method according to claim 8;
disposing another display device substrate so as to face said display device substrate; and
disposing a display medium layer between said display device substrate and said another display device substrate.

14. The method of manufacturing the display device according to claim 13, wherein said display medium layer is a liquid crystal layer.
